(19) United States
(12) Patent Application Publication
(10) Pub. No.: US 2004/0155316 A1
(43) Pub. Date: Aug. 12, 2004

(54) Evaluation wiring pattern and evaluation method for evaluating reliability of semiconductor device, and semiconductor device having the same pattern

(75) Inventors: Yumi Saito, Kanagawa (JP); Hiroshi Tsuda, Kanagawa (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KANAGAWA (JP)

(21) Appl. No.: 10/774,463

(22) Filed: Feb. 10, 2004

(30) Foreign Application Priority Data
Feb. 10, 2003 (JP) 2003-032915

(51) Int. Cl. H01L 29/00

(52) U.S. Cl. 257/536; 257/537; 257/538

(57) ABSTRACT

Provided is a semiconductor reliability evaluating apparatus for evaluating an electro-migration characteristic of a wiring layer which is capable of being formed simply and in a low cost using a reticle set, having a minimum number of reticles, which is capable of measuring an ordinary via plug resistance where the number of wiring layer is two. A first wiring layer and a second wiring layer are configured so that the first wiring layer is connected to the second wiring layer with a plurality of via plugs formed in an insulating layer which is placed between the first wiring layer and the second wiring layer, the first wiring layer and the second wiring layer are made of metals having almost same specific resistances, and each different parasitic resistances are put to at least one of the first wiring layer and the second wiring layer connected to each of the plurality of via plugs to make the total resistance value of the current path through each of the plurality of via plugs different.

### BACKGROUND OF THE INVENTION

1. Field of the Invention

The present invention relates to an evaluation wiring pattern and an evaluation method for evaluating reliability of a semiconductor device, and a semiconductor device having the same pattern, and more particularly to the evaluation wiring pattern and the evaluation method for evaluating an electro-migration characteristic of a wiring layer.

The present application claims priority of Japanese Patent Application No. 2003-032915 filed on Feb. 10, 2003, which is hereby incorporated by reference.

2. Description of the Related Art

As a cause of a defective in a semiconductor device of LSI (Large Scale Integration) or a like, an increasing resistance of a wiring or a break caused by an electro-migration (hereinafter may be referred simply to as an EM) is given.

The EM means that a material in a metal film moves into an electrode component atom from a carrier by a temperature rise of a device which is caused by an increase of a current density in a wiring metal and an increase of a power consumption per one chip and once the EM has occurred, the EM becomes a cause of deterioration in the reliability of the semiconductor device, due to a degradation of the wiring. Consequently an evaluation related to the EM of the wiring used in the device, that is concretely the evaluation for a drift velocity and an incubation time (which is an incubation time to a void creation) is executed.

FIG. 4 is a partial plan view of a wiring pattern for the EM evaluation disclosed in the reference literature 1 and FIG. 5 is a sectional view of FIG. 4. A diffusion layer with silicide (TiSi₂) as a first wiring layer and a aluminum (Al) metal wiring as a second wiring layer are wired through an insulating layer so as to have a wiring pattern configuration in which both the first wiring layer and the second wiring layer are connected with a plurality of via plugs wired in the insulating layer. FIG. 6 is an equivalent circuit of the wiring pattern configuration. Further the wiring pattern configuration of FIG. 5 and the equivalent circuit of FIG. 6 are described in reverse with 180 degrees each other.

In the equivalent circuit of FIG. 6, because a resistance R_{D} of the diffusion layer region is higher than a resistance R_{M} of a metal layer region relatively, when current is passed between a first wiring layer 41 and a second wiring layer 42, at first, most of the current is passed into a current path through via plug V1 whose sum of resistance is the lowest. As a result, voids occur near the place where the via plug V1 and the resistance R_{M} are in contact each other. With the occurrence of voids the resistance of the current path through the via plug V1 becomes higher gradually as a result the most of the current is passed into a current path through a via plug V2 whose total amount of resistance is the second lowest next to the current path through the via plug V1 instead. In the same way described above, the current path where most of the current is passed changes in order from the current path through a via plug V3 to the current path through a via plug V4. As mentioned above, making different the total amount of resistance of current path through each of via plugs leads the value of current which is passed into each of via plugs to be different. Namely, because the current flow shifts to the direction stepwise to higher total resistance value of the current path one after another the shape of electrical resistance increase is shown in a stair shape. It is capable of getting information related to the velocity of drift or incubation time (incubation time until occurrence of void) from increase resistance, which has stair shape. That is, when the resistance of the first wiring layer is fairly high comparing with the electrical resistance of the second wiring layer it is possible to operate a desirable evaluation even in a simple wiring pattern like that showing in FIG. 4.

However to achieve an aim of the present invention using the wiring pattern shown in FIG. 4 it is necessary to form a layer which is like the diffusion layer having high resistance as well as resist to occur the EM phenomenon. If the lower metal wiring and the upper metal wiring are formed as the first wiring layer and as the second wiring layer respectively in the position wiring pattern same as FIG. 4 using a reticle set having a minimum number of reticles for forming two wiring layers with a via plug therebetween, which is capable of measuring an ordinary via plug resistance without forming the diffusion layer, the resistance of the first wiring layer and the resistance of the second wiring layer become to be almost same. Then the each currents which flows through each of the via plugs V1 to V4 respectively become almost same in magnitude as a result it becomes not to be limited that the place where the occurrence of voids is started at first is in proximity to a via plug nearest to an end of the first wiring layer. In other word the occurrence of voids begins in proximity to a via plug far from the end of the first wiring layer, too. Consequently it is impossible to carry out a desirable evaluation because in the wiring pattern like as shown in FIG. 4, the reticle set having a minimum number of reticles for forming two wiring layers with a via plug therebetween, which is capable of measuring the ordinary via plug resistance can not form a wiring pattern for an evaluation. Therefore the wiring pattern for an evaluation has to be formed with use of a reticle set including the diffusion layer. It causes the high cost of manufacture.

To evaluate an electric characteristic of the wiring portion a wiring pattern for an evaluation which is formed using the reticle set having a minimum number of reticles for forming two wiring layers with a via plug therebetween, which is capable of measuring the ordinary via plug resistance is applied. Therefore for getting information related to the velocity of drift or incubation time another new sample which includes the diffusion layer is necessary to be formed. As a result it needs extra number of process and extra manufacturing time and further leads the cost high.

### SUMMARY OF THE INVENTION

In view of the above, it is an object of the present invention to provide to an evaluation wiring pattern and an evaluation method for evaluating reliability of a semiconductor device, and a semiconductor device having the same pattern for evaluating an electro-migration characteristic of a wiring layer, capable of being evaluated at a low cost and with ease using a brief process and a simple mechanism.

According to a first aspect of the present invention, there is provided an evaluation wiring pattern construction for evaluating reliability of a semiconductor device, the pattern construction including: a wiring configuration,

wherein a first wiring layer is connected to a second wiring layer with a plurality of via plugs formed in an insulating layer which is placed between the first wiring layer and the second wiring layer,

wherein the first wiring layer and the second wiring layer are made of metals having almost same specific resistances, and

wherein each different parasitic resistances is put to at least one of the first wiring layer and the second wiring layer connected to each of the plurality of via plugs.

According to a second aspect of the present invention, there is provided an evaluation wiring pattern construction for evaluating reliability of a semiconductor device, the pattern construction including: a wiring configuration,

wherein a first wiring layer is connected to a second wiring layer with a plurality of via plugs formed in an insulating layer which is placed between the first wiring layer and the second wiring layer,

wherein the first wiring layer and the second wiring layer are made of metals having almost same specific resistances, and

wherein the first wiring layer includes a main wiring portion in which current flows in common, and a plurality of branch wiring portions each connected to a corresponding one of the plurality of via plugs so that a current flows with different resistance to a plurality of current paths respectively through the plurality of via plugs from the main wiring portion in the plurality of current paths through the plurality of via plugs.

In the foregoing aspect, a preferable mode is one wherein the plurality of branch wiring portions each connected to a corresponding one of the plurality of via plugs in the first wiring layer are different from each other in length.

3. The evaluation wiring pattern construction according to claim 2, wherein the plurality of branch wiring portions each connected to the corresponding one of the plurality of via plugs in the first wiring layer are different from each other in length.

Another preferable mode is one wherein the plurality of the branch wiring portions is formed to have stepwise great lengths from one side to another side of the plurality of via plugs.

A further preferable mod is one wherein the plurality of branch wiring portions each connected to a corresponding one of the plurality of via plugs in the first wiring layer are different from each other in length.

Also, a preferable mode is one wherein the second wiring layer consists of a main wiring portion in which current flows in common and a plurality of branch wiring portions each connected to a corresponding one of the plurality of via plugs so that a current flows with different resistance to a plurality of current paths respectively through the plurality of via plugs from the main wiring portion in the plurality of current paths through the plurality of via plugs.

Also, a preferable mode is one wherein the plurality of via plugs is evenly spaced at almost regular intervals in line.

Also, a preferable mode is one wherein the plurality of via plugs have same shape.

According to a third aspect of the present invention, there is provided an evaluating method for evaluating reliability of a semiconductor device, using an evaluation wiring pattern construction including: a wiring configuration in which a first wiring layer is connected to a second wiring layer with a plurality of via plugs formed in an insulating layer which is placed between the first wiring layer and the second wiring layer, in which the first wiring layer and the second wiring layer are made of metals having almost same specific resistances, and in which each different parasitic resistances is put to at least one of the first wiring layer and the second wiring layer connected to each of the plurality of via plugs,

wherein a time-variation of resistance is measured flowing a constant current between a first wiring layer and a second wiring layer.

According to a fourth aspect of the present invention, there is provided an evaluating method for evaluating reliability of a semiconductor device, using an evaluation wiring pattern construction including: a wiring configuration in which a first wiring layer is connected to a second wiring layer with a plurality of via plugs formed in an insulating layer which is placed between the first wiring layer and the second wiring layer, in which the first wiring layer and the second wiring layer are made of metals having almost same specific resistances, and in which the first wiring layer includes a main wiring portion in which current flows in common and a plurality of branch wiring portions each connected to a corresponding one of the plurality of via plugs so that a current flows with different resistance to a plurality of current paths respectively through the plurality of via plugs from the main wiring portion in the plurality of current paths through the plurality of via plugs.

wherein a time-variation of resistance is measured flowing a constant current between a first wiring layer and a second wiring layer.

According to a fifth aspect of the present invention, there is provided a semiconductor device having an evaluation wiring pattern construction for evaluating reliability of a semiconductor device, the pattern construction including a wiring configuration,

wherein a first wiring layer is connected to a second wiring layer with a plurality of via plugs formed in an insulating layer which is placed between the first wiring layer and the second wiring layer,

wherein the first wiring layer and the second wiring layer are made of metals having almost same specific resistances, and

wherein each different parasitic resistances is put to at least one of the first wiring layer and the second wiring layer connected to each of the plurality of via plugs.

According to a sixth aspect of the present invention, there is provided a semiconductor device having an evaluation wiring pattern construction for evaluating reliability of a semiconductor device, the pattern construction including a wiring configuration,

wherein a first wiring layer is connected to a second wiring layer with a plurality of via plugs formed in an insulating layer which is placed between the first wiring layer and the second wiring layer,

wherein the first wiring layer and the second wiring layer are made of metals having almost same specific resistances, and

wherein the first wiring layer includes a main wiring portion in which current flows in common and a plurality of branch wiring portions each connected to a corresponding one of the plurality of via plugs so that a current flows with different resistance to a plurality of current paths respectively through the plurality of via plugs from the main wiring portion in the plurality of current paths through the plurality of via plugs.

With the above configuration, with the use of a reticle set having a minimum number of reticles for forming two wiring layers with a via plug therebetween, which is capable of measuring the ordinary via plug resistance, a configuration in which each different parasitic resistance is put to each wire between each via plug and at least one of the first wiring layer and the second wiring layer is formed so that each total resistance values of the current paths through each plurality of via plugs which connects the first wiring layer and the second wiring layer which are made of metals having almost same specific resistances is different from each other. In the prior art mentioned above manufacturing steps need to be executed in order as follows the step of manufacturing the diffusion layer, the step of manufacturing the contact, the step of manufacturing the first wiring layer, the step of manufacturing the via plug, and the step of manufacturing the second wiring layer. However in the present invention the necessary steps of manufacture are only three steps, that is, the step of manufacturing the first wiring layer, the step of manufacturing the via plug, and the step of manufacturing the second wiring layer sequentially. Further the step of ion implantation for forming of the diffusion layer and the step of forming silicide are not required. In the present invention, even in the configuration where the number of the metal wiring layer is two, each total resistance value of each current path through each via plug is set to be different from each other so that wiring layout leads most current to pass through the via plug which is formed on the end of the current path whose total resistance value is the lowest at all times. The resistance of the parasitic resistor can be set at different value by changing the length or the width of the branch wiring portion connected to each via plug. The branch wiring portion is possible to be formed with the main wiring portion at the same time with the use of the reticle same as at least one of the first wiring layer and the second wiring layer. As a result the number of manufacture step becomes smaller and the forming time becomes shorter comparing with the conventional method, that is, a cost reduction is realizable.

With the above configurations, the semiconductor reliability evaluating device which allows to get information about the drift velocity and the incubation time (which is the incubation time until the void creation) is capable of being formed by the reticle set having the minimum number of reticles which is capable of measuring the ordinary via plug resistance of the current path in which the number of wiring layer having almost same resistance is two. Especially an improvement of the EM tolerance is a serious subject because of the fining wire associating with the fining LSI. For this reason a method to promote the reliability of the metal wire by adding different kinds of elements to the wire which is made of copper (Cu) or aluminum (Al) mainly becomes a focus of attention. In that case evaluation to obtain the drift velocity and the incubation time (which is the incubation time until the void creation) which are important parameters can be carried out using evaluation wiring pattern formed by only metal layer with just the reticle set having a minimum number of reticles. Therefore not only the cost of the reticle but also the cost of producing the evaluation sample are capable of being cut significantly. And the EM characteristic is able to be measured well similarly to the case disclosed in “1996 Symposium on VLSI Technology Digest of Technical Papers, p192 (1996)” with the constant current flow between the first wiring layer and the second wiring layer in the semiconductor reliability evaluating device of the present invention. Particularly even in a case a metal wire having low resistances is used as both of the first wiring layer and the second wiring layer it is available to measure the EM characteristic excellently.

### BRIEF DESCRIPTION OF THE DRAWINGS

The above and other objects, advantages, and features of the present invention will be more apparent from the following description taken in conjunction with the accompanying drawings in which:

FIG. 1 is a partial plan diagram showing schematically a wiring pattern for evaluating an electro-migration which may occur in a semiconductor device using an evaluation apparatus for evaluating reliability of a semiconductor device according to a preferable embodiment of the present invention;

FIG. 2 is an equivalent circuit diagram equivalent to an electrical configuration of the wiring pattern for evaluating electro-migration as shown in FIG. 1;

FIG. 3 is a time-variation of resistance of the wiring pattern for the electro-migration evaluation shown n FIG. 1;

FIG. 4 is a partial plan view of a conventional wiring pattern for an electro-migration evaluation;

FIG. 5 is a sectional view of the conventional wiring pattern for the electro-migration evaluation showing in FIG. 4; and

FIG. 6 is an equivalent circuit of the conventional wiring pattern for the electro-migration evaluation showing in FIG. 4.

### DESCRIPTION OF THE PREFERRED EMBODIMENTS

Best modes of carrying out the present invention will be described in further detail using various embodiments with reference to the accompanying drawings.

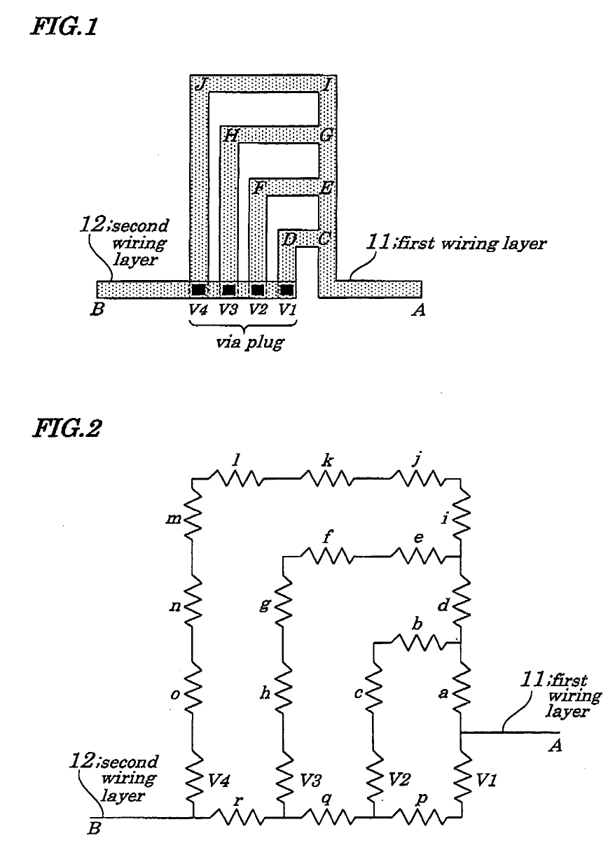

FIG. 1 is a partial plan diagram showing schematically an evaluation wiring pattern for evaluating an electro-migration which may occur in a semiconductor device using an evaluation apparatus for evaluating reliability of a semiconductor device (hereinafter, may be simply referred to as semiconductor evaluating apparatus) according to a preferable embodiment of the present invention. FIG. 2 is an equivalent circuit diagram equivalent to an electrical configuration of the wiring pattern for evaluating electro-migration as shown in FIG. 1.

The evaluation wiring pattern of the semiconductor device according to the embodiment is formed using a reticle set having a minimum number of reticles, such that it is capable of measuring a resistance of an ordinary via plug with which two layers of wiring layers are connected between each other.

In the evaluation wiring pattern of the semiconductor device as shown in FIG. 1, a first wiring layer 11 as a lower wiring layer and a second wiring layer 12 as an upper wiring layer, each are made of a same metal or a different metal having an almost same value in specific resistance (resistivity). The first wiring layer 11 and the second wiring layer 12 are connected between each other with a plurality of via plugs V1 to V4 (made of metal berapparentied in via holes, each of which is formed in an insulating layer (not shown), such as an interlayer dielectric sandwiched between the first wiring layer 11 and the second wiring layer 12. As shown in FIG. 1, the plurality of via plugs V1 to V4 are evenly spaced at (almost) regular intervals in a manner of a linear arrangement.

The first wiring layer 11 is made up of a main wiring portion (A˜C) which serves as a common wiring portion in a plurality of current paths (C→V1→B, C→V2→B, C→V3→B, and C→V4→B) through each of via plugs, and a plurality of branch wiring portions C˜V1, C˜V2, C˜V3, and C˜V4, each of which is connected to a corresponding via plug V1, V2, V3 or V4, so that a total resistance value of each current path including the corresponding via plug V1, V2, V3 or V4 increases in order of branch wiring portions C˜V1, C˜V2, C˜V3, and C˜V4.

That is, the current paths including the corresponding via plugs V1, V2, V3 or V4 are set be different from one another in total resistance value. In FIG. 1, configuration having four via plugs V1 to V4 is shown as one example. As repeated in detail, in the first wiring layer 11, the branch wiring portions C˜V1, C˜V2, C˜V3, and C˜V4 correspond to regions (C→D→V1, C→E→F→V2, C→G→H→V3, and C→I→J→V4) between a point “C” and each of via plugs V1, V2, V3 and V4, whereas the main wiring portion (A˜C) corresponds to a common region from the point “C” to a end point “A” of the first wiring layer 11. In the embodiment, the first wiring layer 11 may be made of copper having a width of 0.18 μm, the second wiring layer 122 may be made of copper having a width of 0.18 μm, and similarly the via plug V1, V2, V3 and V4 each may be made of copper having a diameter of 0.18 μm. Also, for example a silicon oxide may be used as the insulating material (not shown). However the invention is not limited to those as above in the materials and size of wiring lays and the insulating layer.

In the equivalent circuit of FIG. 2, V1, V2, V3, and V4 are via plugs respectively and resistors from “a” to “r” are parasitic resistors. Each resistances of the via plugs and the parasitic resistors are R_{V1}, • • • R_{V4}, Rₐ, • • • Rᵣ. The four via plugs are made in a same shape. In the embodiment of the present invention changing the length of the branch wire of the first wiring layer causes the change of the total resistance value of wire between the main wiring layer region and the via plug. Consequently the total resistance value R₁ (R_{V1}+Rₚ+R_{q}+Rᵣ=R₁) in the current path through V1 is lowest and the total resistance value R₂ (Rₐ+R_{b}+R_{c}+R_{V2}+R_{q}+Rᵣ=R₂) in the current path through V2, the total resistance value R₃ (Rₐ+R_{d}+Rₑ+R_{f}+R_{g}+Rₕ+R_{V3}+Rᵣ=R₃) in the current path through V3, and the total resistance value R₄ (Rₐ+R_{d}+Rᵢ+Rⱼ+Rₖ+Rₗ+Rₘ+Rₙ+Rₒ+R_{V4}=R₄) in the current path through V4 are ordered from lowest to highest after the total resistance value R₁ sequentially. The resistances Rₐ to Rₒ of the parasitic resistors “a” to “o” are almost same and also the resistances Rₚ to Rᵣ of the parasitic resistors “p” to “r” are almost same. Still the first wiring layer and the second wiring layer are interchangeable up and down. A parasitic resistor of a branch wiring portion C˜V1 is not shown in FIG. 2 for simplification of explanation. Similarly, a parasitic resistor corresponding to the branch wiring portion C˜V1 out of a parasitic resistor of each of branch wiring portions C˜V2, C˜V3, and C˜V4 is not shown in FIG. 2.

With use of such like wiring pattern mentioned above when a constant current flows through the first wiring layer 11 and the second wiring layer 12, at the beginning most current flows through the via plug V1 selecting the current path through the via plug V1 as the current path whose total resistance value is lowest. And next the resistance of the current path through the via plug V1 becomes higher, at the same time the total resistance value becomes a bit higher because voids occur near the place of the via plug V1 caused by the EM phenomenon. Then next, most current begins to pass through the via plug V2 whose total resistance value is the second lowest. After a while most current begins to pass through the via plug V3 because voids occur near the place of the via plug V2 caused by the EM phenomenon as a result the resistance of this current path through V2 becomes higher. The following is same as above, voids occur near the via plug V3 as a result most current flow shifts to the via plug V4. By monitoring the change in the state mentioned above as a time-variation of resistance it is possible to get information about a growth velocity (corresponding to a drift velocity of a composing atom) of voids in the junction region of the second wiring layer and via plugs and an incubation time until the voids occur.

An explanation about a case in which an EM test is run with the practical current flow in the EM evaluating wiring pattern shown in FIG. 1 is followed. A constant current is flowed from the first wiring layer to the second wiring layer charging “A” side of the first wiring layer negatively and “B” side of the second wiring layer positively in FIG. 1. The current flows at 0.5˜2 MA/cm² in wire and the temperature is set at 250° C.˜350° C. At the beginning of the test, it is clear from the equivalent circuit of FIG. 2, most current flows through the via plug V1 selecting the current path through the via plug V1 as the current path whose total resistance value is lowest. As a result the occurrence of voids by the effect of the EM near the via plug V1 leads the increase of the resistance of this current path. Consequently the total resistance value of the current path through the via plug V1 becomes high, then, most current begins to flow over the current path through the via plug V2 whose total resistance value is the second lowest. As a result voids occur near the via plug V2 so as to increase the resistance of the current path through the via plug V2. Continually the current flow shifts from the current path through the via plug V3 to the current path through the via plug V4.

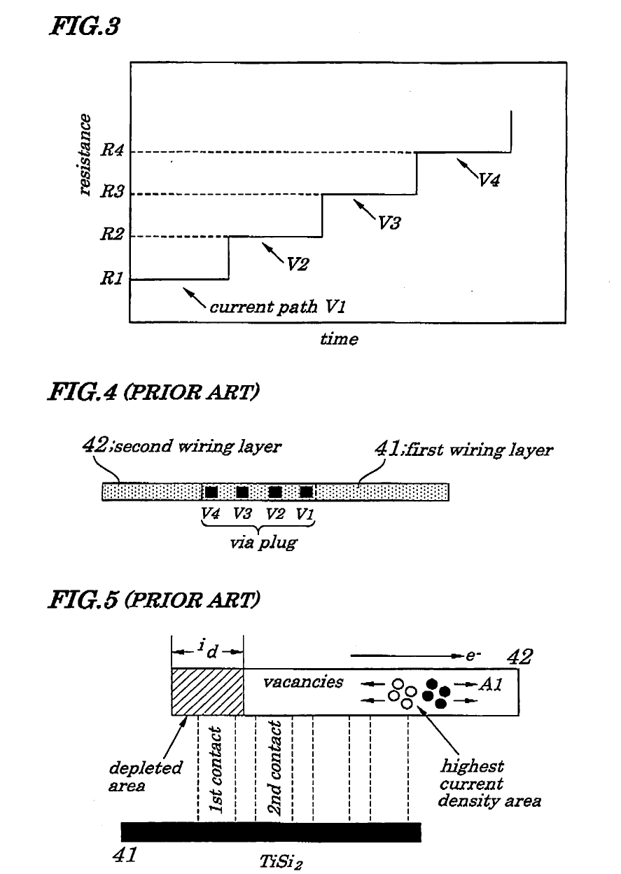

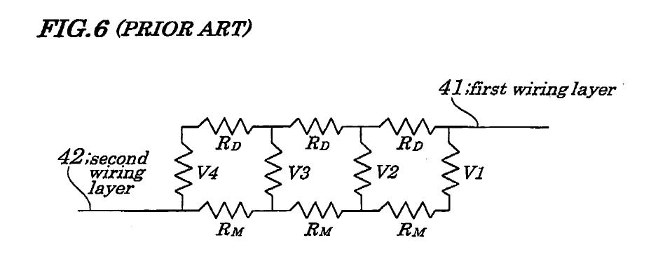

As described above, at first the current begins to flow over the path whose initial total resistance value is the lowest, that is, the path including the junction region of via plug in which the wire used is the shortest. Next, because of the resistance increase caused by the occurrence of voids near the via plug the main current path goes to the current path whose wire used is the second shortest which is next to the current path whose wire used is the shortest. On this occasion it is recognized that the resistance increases stepwise in accordance with the elapse of time by monitoring the time-variation of resistance. The monitored resistance also increases stepwise like R1→R2→R3→R4 according to the shift of the main current path from the current path through the via plug V1 to the current path through the via plug V2, the current path through the via plug V3, and the current path through the via plug V4 sequentially. FIG. 3 shows a state of this resistance variation mentioned above. A method to determine the incubation time until the occurrence of voids of the wiring composed metal in the EM and the drift velocity of atom referencing to the step-wise resistance variation is omitted because the method is already disclosed in the reference literature 1.

It is apparent that the present invention is not limited to the above embodiment but may be changed and modified without departing from the scope and spirit of the invention. For example, in the above embodiment, changing the length of the branch wiring portion of the first wiring layer causes the change of the total resistance value of the current path through the each via plug.

Additionally, it is also possible that changing the width of the wire of the branch wiring portion causes the change of the total resistance value. Furthermore, both of the length of wire and the width of wire can be changed. And in the above embodiment however the branch wiring portion is composed in the first wiring layer, the branch wiring portion is also able to be composed in the second wiring layer, the junction region can be composed in both of the first wiring layer and the second wiring layer. Still more the first wiring layer and the second wiring layer are not necessary to be made of same kind metal, it means that they are possible to be made of different kind of metals.

### AMENDMENTS TO THE SPECIFICATION

Please cancel the originally-filed abstract of the disclosure, and add the accompanying new abstract of the disclosure which appears on a separate sheet in the appendix.

What is claimed is:

1. An evaluation wiring pattern construction for evaluating reliability of a semiconductor device, said pattern construction comprising a wiring configuration,
wherein a first wiring layer is connected to a second wiring layer with a plurality of via plugs formed in an insulating layer which is placed between said first wiring layer and said second wiring layer,
wherein said first wiring layer and said second wiring layer are made of metals having almost same specific resistances, and
wherein each different parasitic resistances is put to at least one of said first wiring layer and said second wiring layer connected to each of said plurality of via plugs.

2. An evaluation wiring pattern construction for evaluating reliability of a semiconductor device, said pattern construction comprising a wiring configuration,
wherein a first wiring layer is connected to a second wiring layer with a plurality of via plugs formed in an insulating layer which is placed between said first wiring layer and said second wiring layer,
wherein said first wiring layer and said second wiring layer are made of metals having almost same specific resistances, and
wherein said first wiring layer comprises a main wiring portion in which current flows in common, and a plurality of branch wiring portions each connected to a corresponding one of said plurality of via plugs so that a current flows with different resistance to a plurality of current paths respectively through said plurality of via plugs from said main wiring portion in said plurality of current paths through said plurality of via plugs.

3. The evaluation wiring pattern construction according to claim 2, wherein said plurality of branch wiring portions each connected to said corresponding one of said plurality of via plugs in said first wiring layer are different from each other in length.

4. The evaluation wiring pattern construction according to claim 3, wherein said plurality of said branch wiring portion are formed to have stepwise great lengths from one side to another side of said plurality of via plugs.

5. The evaluation wiring pattern construction according to claim 2, wherein said plurality of branch wiring portions each connected to a corresponding one of said plurality of via plugs in said first wiring layer are different from each other in length.

6. The evaluation wiring pattern construction according to claim 2, wherein said second wiring layer comprises a main wiring portion in which current flows in common and a plurality of branch wiring portions each connected to a corresponding one of said plurality of via plugs so that a current flows with different resistance to a plurality of current paths respectively through said plurality of via plugs from said main wiring portion in said plurality of current paths through said plurality of via plugs.

7. The evaluation wiring pattern construction according to claim 1, wherein said plurality of via plugs is evenly spaced at almost regular intervals in line.

8. The evaluation wiring pattern construction according to claim 7, wherein said plurality of via plugs have same shape.

9. The evaluation wiring pattern construction according to claim 2, wherein said plurality of via plugs is evenly spaced at almost regular intervals in line.

10. The evaluation wiring pattern construction according to claim 9, wherein said plurality of via plugs have same shape.

11. An evaluation method for evaluating reliability of a semiconductor device, using an evaluation wiring pattern construction comprising a wiring configuration in which a first wiring layer is connected to a second wiring layer with a plurality of via plugs formed in an insulating layer which is placed between said first wiring layer and said second wiring layer, in which said first wiring layer and said second wiring layer are made of metals having almost same specific resistances, and in which each different parasitic resistances is put to at least one of said first wiring layer and said second wiring layer connected to each of said plurality of via plugs,
wherein a time-variation of resistance is measured flowing a constant current between a first wiring layer and a second wiring layer.

12. An evaluation method for evaluating reliability of a semiconductor device, using an evaluation wiring pattern construction comprising a wiring configuration in which a first wiring layer is connected to a second wiring layer with a plurality of via plugs formed in an insulating layer which is placed between said first wiring layer and said second wiring layer, in which said first wiring layer and said second wiring layer are made of metals having almost same specific resistances, and in which said first wiring layer comprises a main wiring portion in which current flows in common and a plurality of branch wiring portions each connected to a corresponding one of said plurality of via plugs so that a current flows with different resistance to a plurality of current paths respectively through said plurality of via plugs from said main wiring portion in said plurality of current paths through said plurality of via plugs.
wherein a time-variation of resistance is measured flowing a constant current between a first wiring layer and a second wiring layer.

13. The evaluation wiring pattern construction according to claim 12, wherein said plurality of branch wiring portions each connected to a corresponding one of said plurality of via plugs in said first wiring layer are different from each other in length.

14. The evaluation wiring pattern construction according to claim 13, wherein a length of said branch wiring portion is formed to have stepwise great lengths from one side to another side of said plurality of via plugs.

15. A semiconductor device having an evaluation wiring pattern construction for evaluating reliability of a semiconductor device, said pattern construction comprising a wiring configuration,
wherein a first wiring layer is connected to a second wiring layer with a plurality of via plugs formed in an insulating layer which is placed between said first wiring layer and said second wiring layer,
wherein said first wiring layer and said second wiring layer are made of metals having almost same specific resistances, and
wherein each different parasitic resistances is put to at least one of said first wiring layer and said second wiring layer connected to each of said plurality of via plugs.

16. A semiconductor device having an evaluation wiring pattern construction for evaluating reliability of a semiconductor device, said pattern construction comprising a wiring configuration,
wherein a first wiring layer is connected to a second wiring layer with a plurality of via plugs formed in an insulating layer which is placed between said first wiring layer and said second wiring layer,
wherein said first wiring layer and said second wiring layer are made of metals having almost same specific resistances, and
wherein said first wiring layer comprises a main wiring portion in which current flows in common and a plurality of branch wiring portions each connected to a corresponding one of said plurality of via plugs so that a current flows with different resistance to a plurality of current paths respectively through said plurality of via plugs from said main wiring portion in said plurality of current paths through said plurality of via plugs.
